(19) United States
(12) Patent Application Publication
(10) Pub. No.: US 2013/0248964 A1
(43) Pub. Date: Sep. 26, 2013

(54) NONVOLATILE SEMICONDUCTOR MEMORY DEVICE AND MANUFACTURING METHOD THEREOF

(71) Applicant: KABUSHIKI KAISHA TOSHIBA, Tokyo (JP)

(72) Inventors: Kenichiro TORATANI, Kanagawa (JP); Masayuki Tanaka, Mie (JP)

(73) Assignee: Kabushiki Kaisha Toshiba, Tokyo (JP)

(21) Appl. No.: 13/786,322

(22) Filed: Mar. 5, 2013

(30) Foreign Application Priority Data
Mar. 21, 2012 (JP) 2012-064450

(51) Int. Cl. H01L 29/788; H01L 29/66

(52) U.S. Cl. CPC H01L 29/788; H01L 29/66825
USPC 257/315; 438/264

(57) ABSTRACT

According to one embodiment, a nonvolatile semiconductor memory device includes a semiconductor substrate, a first insulation film formed on a semiconductor substrate, a charge storage film formed on the first insulation film, a second insulation film formed on the charge storage film, and a control electrode formed on the second insulation film. The first insulation film is formed on the semiconductor substrate, and has a lower layer film containing silicon, and an upper layer film formed on the lower layer film, the upper layer film having a concentration of transition metal atoms containing at least one of hafnium, titanium, zirconium, tantalum or lanthanum from 1e13 atoms/cm² to 1e16 atoms/cm² and is formed by either an oxide film, a nitride film, or an oxynitride film.

### CROSS-REFERENCE TO RELATED APPLICATION

This application is based upon and claims the benefit of priority from Japanese Patent Application No. 2012-064450, filed Mar. 21, 2012; the entire contents of which are incorporated herein by reference.

### FIELD

Embodiments described herein relate a nonvolatile semiconductor memory device and manufacturing method thereof.

### BACKGROUND

In a floating gate electrode type nonvolatile semiconductor memory device, a memory cell transistor is provided on a semiconductor substrate. The memory cell transistor contains a tunnel insulating film (TNL film) formed on the semiconductor substrate, a floating gate (FG) electrode formed thereon, an interpoly dielectric film (IPD film), and a control gate (CG) electrode formed thereon.

During the writing operation of the semiconductor memory device, electric charges will be injected from the semiconductor substrate into the FG electrode through the TNL film due to the tunnel effect. During the erasing operation of the semiconductor memory device, electric charges stored in the FG electrode will be extracted from the FG electrode to the semiconductor substrate through the TNL film, due to the tunnel effect.

When repeating the writing/erasing operations as described above, the TNL film of the semiconductor memory device is likely to deteriorate due to repeated high stress. As a result, the reliability of the semiconductor memory device deteriorates.

### DESCRIPTION OF THE DRAWINGS

FIG. 1 shows one example of a plan view of a nonvolatile semiconductor memory device according to one embodiment.

FIGS. 2A and 2B show one example of cross-sectional views of the nonvolatile semiconductor memory device of FIG. 1.

FIGS. 3A and 3B show one example of the manufacturing process of a nonvolatile semiconductor memory device according to one embodiment.

FIGS. 3C and 3D show one example of the manufacturing process of the nonvolatile semiconductor memory device in the present embodiment.

FIGS. 3E and 3F show one example of the manufacturing process of the nonvolatile semiconductor memory device in the present embodiment.

FIGS. 3G and 3H show one example of the manufacturing process of the nonvolatile semiconductor memory device in the present embodiment.

FIG. 4 is a graph showing one example of the relationship of leak current to atomic concentration of hafnium.

FIGS. 5A and 5B show cross-sectional views of a nonvolatile semiconductor memory device according to another embodiment.

### DETAILED DESCRIPTION

In general, embodiments will be described with reference to the drawings. However, it is not limited to embodiments of the present disclosure. In addition, common numerals will be used to describe the parts repeatedly appearing throughout all the drawings. Since the drawings are schematic diagrams to facilitate the understanding and description of the embodiment, with consideration to following descriptions and known technology, shapes, sizes and ratios in the drawings that may be changed to be different from the actual device.

According to the disclosure, a nonvolatile semiconductor memory device includes a semiconductor substrate, a first insulation film formed on the semiconductor substrate, a charge storage film formed on the first insulation film, a second insulation film formed on the charge storage film, and a control electrode formed on the second insulation film. In this nonvolatile semiconductor memory device, the first insulation film is formed on the semiconductor substrate, and includes a lower layer film containing silicon, and an upper layer film, formed on the lower layer film, with a concentration of transition metal atoms, including at least one of hafnium, titanium, zirconium, tantalum or lanthanum, from 1e13 atoms/cm² (1×10¹³ atoms per square centimeter) to 1e16 atoms/cm² (1×10¹⁶ atoms per square centimeter) , the upper layer film of which is formed by either an oxide film, a nitride film or an oxynitride film.

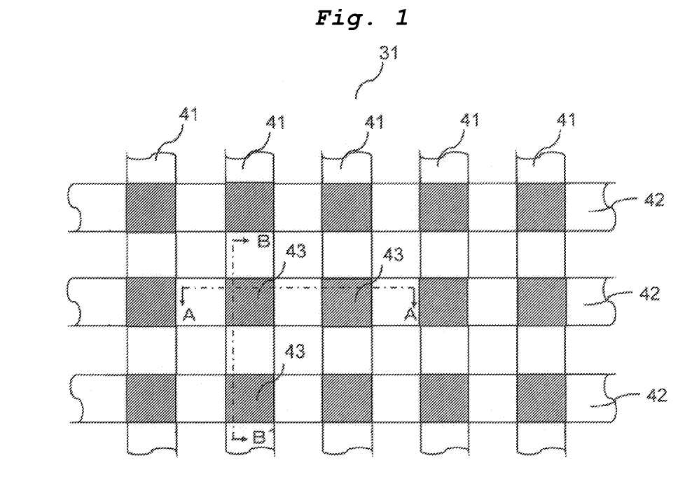

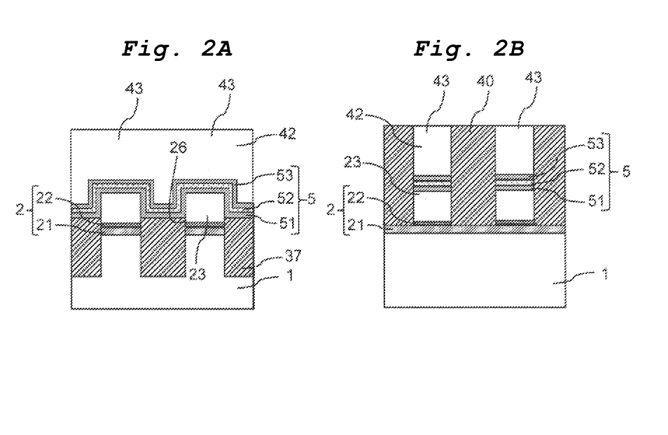

FIG. 1 and FIGS. 2A and 2B describe a floating gate (FG)-type semiconductor memory device (nonvolatile semiconductor memory device) 31 in the present disclosure. Although examples are applicable to a TNL film 2 (first insulating film) in the semiconductor memory device 31, it is not limited to this embodiment and can also be applied to other semiconductors and parts thereof.

FIG. 1 shows one example of the plan view of the memory cell area in the semiconductor memory device 31 of the present embodiment. Moreover, the plan view for a modified example of the memory cell area in the semiconductor memory device 31 will be explained later is also shown in the FIG. 1.

As shown in FIG. 1, a plurality of bit lines 41 is formed along the vertical direction of the paper surface on the semiconductor memory device 31. These plurality of bit lines are arranged at regular intervals in the transverse direction of the paper surface, parallel to each other. A plurality of word lines 42 (control gate (CG) electrode) is formed so that as to be orthogonal as seen in the plan view with the multiple bit lines 41. A plurality of memory cell transistors 43 are formed at several locations where each bit line 41 and each word line 42 intersect. In other words, a plurality of memory cell transistors 43 are positioned in a matrix form in the memory cell area of the semiconductor memory device 31.

The cross-sectional view of the semiconductor memory device 31 is used to explain the semiconductor memory device 31 of this embodiment. FIG. 2A and FIG. 2B are one example of cross-sectional views of the memory cell area in the semiconductor memory device 31. More specifically, FIG. 2A is the cross-sectional view of the semiconductor memory device 31 taken along the A-A line in FIG. 1, while FIG. 2B is the cross-sectional view of the semiconductor memory device 31 taken along the B-B′ line in FIG. 1.

As shown in FIG. 2A, the semiconductor memory device 31 in this embodiment has a semiconductor substrate 1 and a plurality of memory cell transistors 43 formed on the semiconductor substrate 1. Memory cell transistors 43 include a lamination (film stack) of the TNL film 2 (first insulating film) and the FG electrode 23 (charge storage film). Each memory cell transistor 43 is separated by an element isolation trench 26 formed on the semiconductor substrate 1. This element isolation trench 26 is embedded with an element isolation insulating film 37 formed by a silicon dioxide film. An IPD film 5 (second insulating film) is formed so that it covers the upper surface of the memory cell 43 and the upper surface of the element isolation insulating film 37, on which a CG electrode (control electrode) 42 is formed. Moreover, the IPD film 5 includes an ONO film, which is a lamination of a silicon dioxide film 51 on the FG electrode 23, a silicon nitride film 52 formed on the silicon dioxide film 51, and a silicon dioxide film 53 formed on the silicon nitride film 52. However, the IPD film 5 is not limited to the ONO film as shown in this embodiment; the films may comprise other insulation films or lamination of insulation films can also serve the same purpose. At this point, the FG electrode 23 may be formed of an insulating film such as silicon nitride film or lamination of silicon and an insulating film.

Specifically, the TNL film 2 includes a lower layer film 21 formed by a silicon dioxide film on the semiconductor substrate 1, and an upper layer film 22 formed by a hafnium oxide film formed on the lower layer film 21.

As shown in FIG. 2B, the semiconductor memory device 31 in this embodiment has a semiconductor substrate 1 and a plurality of memory cell transistors 43 formed on the substrate 1. The IPD film 5 and the CG electrode 42 are formed on the memory cell transistors 43, and the memory cell transistors 43 adjacent to each other are separated by an interlayer dielectric film 40 formed of a silicon dioxide film.

In this embodiment, the material used for the lower layer film 21 in the TNL film 2 is not limited to a silicon oxide film; a silicon oxynitride film, a laminated film of silicon oxide film/silicon nitride film or a laminated film of silicon oxide film/silicon nitride film/silicon oxide film can also be used.

Moreover, the atom contained in the upper layer film 22 is not limited to the hafnium atom, but it may also include transition metal atoms such as titanium, zirconium, tantalum, lanthanum, and so on. Such atom has characteristics that can be used to stabilize oxygen deficiency. In other words, the oxygen density of the upper layer film 22 formed by the hafnium oxide film (or other transition metals) is to be less than the oxygen density of the lower layer film 21 formed by the silicon oxide film. In one aspect, oxygen density of the upper layer film 22 is less than the oxygen density of the lower layer film 21 at the interface of these films . In other words, the bonding of atoms contained in the upper layer film 22 is not completely blocked, which will be explained in detail later.

Furthermore, the material used for the upper layer film 22 in the TNL film 2 is not limited to the hafnium oxide film; a hafnium nitride film, a hafnium silicon oxide film, a hafnium silicon nitride film, or a hafnium silicon oxynitride film can also be used. When a nitride film is used as the upper layer film 22, it will be able to avoid the so-called “bird's beak effect” at the interface with the FG electrode 23. This bird beak effect is caused by a characteristic variation of memory cell transistors 43. If a hafnium silicon oxide film is used as the upper layer film 22, it will be able to form a stable and low concentration of hafnium atoms in the upper layer film 22. The above two effects can be achieved if the hafnium silicon nitride film and the hafnium silicon oxynitride film are used as the upper layer film 22.

In one embodiment, the concentration of atoms, such as the hafnium atom, contained in the upper layer film 22 is higher than 1e13 atoms/cm² and lower than 1e16 atoms/cm², the detail of which will be explained later. For example, if the upper layer film 22 is formed by a hafnium oxide film with a concentration of hafnium atoms between 1e13 atoms/cm² and 1e16 atoms/cm², the film thickness of the upper layer film 22 shall be in the range of 0.01 nm to 3 nm. In other words, in order to form a bond that is not blocked, the upper layer film 22 is formed as a thin atomic layer. For example, the upper layer film 22 is a thin film having a thickness of about 1 atomic layer, while the lower layer film 21 is a film formed by adsorbing hafnium atoms and arranging a plurality of hafnium atoms in parallel.

Moreover, although the upper layer film 22 in this embodiment is described as a film, the upper layer film 22 is not limited to the shape of a film. The atoms, such as the hafnium atom, may be present between the lower layer film 21 and the FG electrode 23.

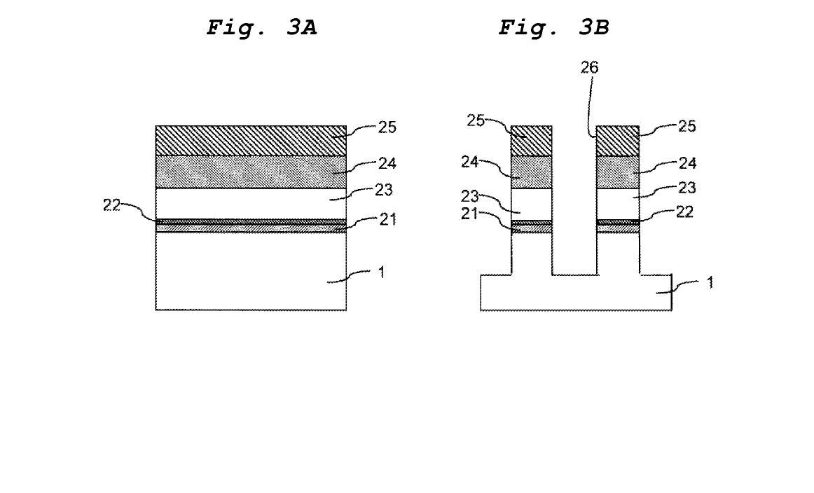

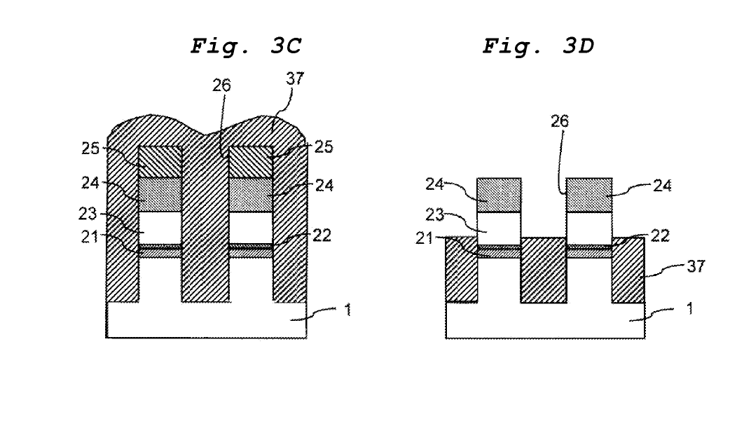

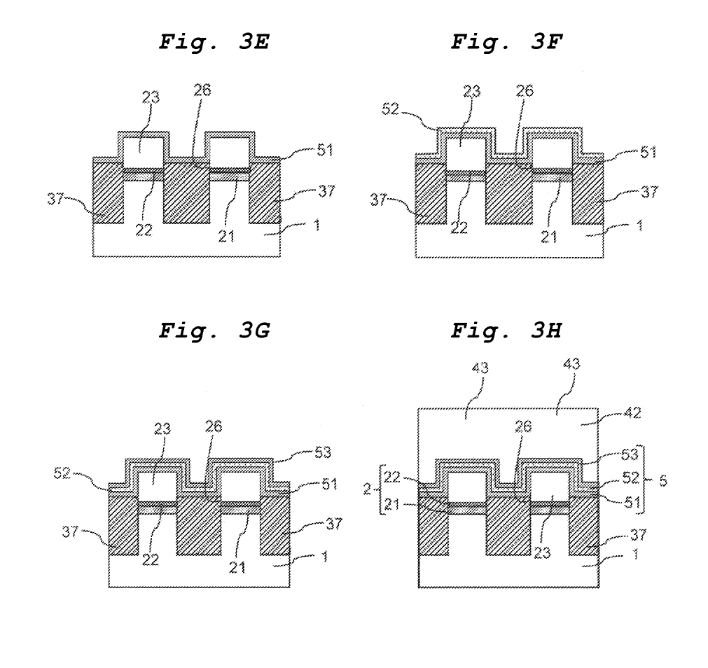

Next, FIG. 3A to FIG. 3H are schematic cross-sectional views used to explain the manufacturing method of the semiconductor memory device 31 according to one embodiment. FIG. 3A to FIG. 3H show cross-sectional views of the memory cell area of the semiconductor memory device 31, specifically those corresponding to the cross-section of the semiconductor memory device 31 in FIG. 2A. In this case, the lower layer film 21 made from a silicon oxide film, and the upper layer film 22 made from a hafnium oxide film will be used in the explanation.

Using the well-known methods such as a thermal oxidation process, the lower layer film 21 made from the silicon oxide layer is formed on the semiconductor substrate 1 (a p-type silicon substrate or a p-type well formed on an n-type silicon substrate) so that its thickness is, for example, within the range of about 1 nm to 15 nm.

Using an ALD (Atomic Layer Deposition) method, the upper layer film 22 made from a hafnium oxide film is formed on the lower layer film 21 so that its thickness is, for example, within the range of about 0.01 nm to 3 nm. To be precise, the formation of the upper layer film 22 made from the hafnium oxide film can be carried out by, when using the ALD method, by introducing tetra ethyl methyl amino hafnium (TEMAHf) and a purge, and the introduction of ozone and a purge as one cycle, and by repeating this cycle from 1 to 20 times under the film formation temperature of 300° C. In one embodiment, the oxygen density of the upper layer film 22 made from the hafnium oxide film is to be less than that of the lower layer film 21 made from the silicon dioxide film. The oxygen density of the upper layer film 22 is less than the oxygen density of the lower layer film at the interface of these films. In other words, the bonding of hafnium atoms contained in the lower layer film 22 is not to be completely blocked. Therefore, during the formation of the upper layer film 22, impurities, such as carbons and other impurities, are minimized, in order not to block the bonding of the hafnium atoms. More specifically, the concentration of the hafnium atoms contained in the upper layer film 22 is within the range of 1e13 atoms/cm² and 1e16 atoms/cm².

The formation method of the upper layer film 22 is not limited to the ALD method as various methods can be used, such as a sputtering method whose film formation conditions are, for example, 300 W in voltage, 1 Pa in film formation pressure, and 100 sccm in Ar gas flow rate . Other methods such as a plasma CVD (Chemical Vapor Deposition) method, a coating method, an atomization method can also be used. As for the hafnium source, it is not limited to TEMAHf; hafnium chloride (HfCl₄) , tetra dimethyl amino hafnium (TDMAHf) and others can also be used. The oxidant is not limited to ozone; water, oxygen, nitrous oxide, or, oxygen radicals excited by physical methods can also be used as the oxidants. The formation of the upper layer film 22 may be carried out under conditions capable of forming a thin film, for example, at a formation temperature within the range from room temperature to about 500° C.

If a hafnium nitride film is used instead of the hafnium oxide film to form the upper layer film 22, a nitriding agent, instead of oxidants, is used to form the upper layer film 22. Ammonia, hydrazine, or nitrogen radicals excited by a physical method can be used as the nitriding agents. In the same way, if a hafnium oxynitride film is to be formed, it would be appropriate to use the oxidant and the nitriding agent.

Formed on the upper layer film 22 is an FG electrode 23 made from, for example, a polysilicon film, by a CVD method, so that its film thickness becomes, for example, about 10 nm to 50 nm. Then, a first mask material 24, formed thereon by a CVD method, is made from, for example, a silicon nitride film, so that its film thickness would be, for example, within the range of 50 nm to 200 nm. Furthermore, a second mask material 25 is formed on the first mask material 24 by a CVD method. The second mask material 25 is made from, for example, a silicon oxide film, so that its film thickness would be, for example, within the range of 50 nm to 400 nm. In this way, the configuration shown in FIG. 3A can be obtained.

Photoresist (not shown in the drawing) is coated onto the second mask material 25, and patterning is carried out on the photoresist by a pattern exposure method. Next, patterning of the second mask material 25 is carried out by using the photoresist as a mask resistant to etching, and etching of the second mask material 25 may be performed. After the photoresist is removed, the second mask material 25 that has been patterned is used as a mask to etch the first mask material 24, the FG electrode 23, the gate insulation film 22, and the semiconductor substrate 1 to form the element isolation trench 26, so as to obtain the configuration shown in FIG. 3B.

The element isolation trench 26 is embedded with the element isolation insulating film 37 formed by a silicon dioxide film having a film thickness of, for example, 200 nm to 1,500 nm, using the well-known methods, such as a coating method and other methods, so as to obtain the configuration shown in FIG. 3C.

A densification treatment on the element isolation insulating film 37 is carried out under oxygen atmosphere or steam atmosphere. After the removal of the second mask material 25, the first mask material 24 made from a silicon nitride film used as an etch stop to flatten the element isolation insulating film 37 by the method of chemical mechanical polishing (CMP). Next, under selective etching conditions with the silicon nitride film, the upper surface of the element isolation insulating film 37 made from a silicon oxide film is etched, so as to obtain the configuration shown in FIG. 3D.

Moreover, a silicon oxide film 51 having a film thickness, for example, from 1 nm to 10 nm is formed using the well-known methods such as a low-pressure chemical vapor (LP-CVD) method so that the FG electrode 23 and the element isolation insulating film 37 are covered, obtaining the configuration shown in FIG. 3E.

A silicon nitride film 52 with a film thickness of, for example, 1 nm to 5 nm is formed onto the silicon oxide film 51 to obtain the configuration shown in FIG. 3F. Several methods can be used to form the silicon nitride film 52, including, for example, a radical nitriding method, an ALD method, an LP-CVD method, a plasma CVD method, a PVD (Physical Vapor Deposition) such as a sputtering method, a thermal nitridation method by an ordinary electric furnace, and the like.

Similarly like the formation method of the silicon oxide film 51, a silicon dioxide film 53 with a film thickness of, for example, about 1 nm to 10 nm is formed on the silicon nitride film 52 to obtain the configuration shown in FIG. 3G. Moreover, at this stage, a densification treatment (thermal treatment) is performed in order to increase the density of each film and improve the layer interface, oxygen compensation, or oxidation treatment for interface improvement.

The configuration in FIG. 3H can be obtained by forming a CG electrode 42 on the silicon oxide film 52. Furthermore, after carrying out a patterning treatment of the CG electrode 42 by an exposure method, the semiconductor memory device 31 can be obtained through the well-known processes.

In this embodiment, by using a laminated structure made by a silicon oxide film (lower layer film) 21 and a hafnium oxide film (upper layer film) 22 as the TNL film 2, leakage current increases during an erase operation of the semiconductor memory device 31 so as to improve the erasing characteristics. Consequently, the improvement of the erasing operation mitigates the stress on the TNL film 2 during the erasing operation, which further avoids the deterioration of the TNL film 2, and eventually improves the durability, charge retention ability and reliability of the semiconductor memory device 31. That is, the semiconductor memory device 31 according to the embodiments is able to provide excellent device characteristics and reliability. Moreover, because of the improvement of the erasing operation, the erasing voltage applied on the semiconductor memory device 31 during the erasing operation can be lowered. By using a laminated structure made by a silicon oxide film 21 and a hafnium oxide film 22 to increase the leakage current will be explained later.

When the silicon oxide film 21 and the hafnium oxide film 22 are laminated, in other words, when the different oxide films are layered as described herein, the oxygen density in the interface is different. To mitigate the differences in oxygen density at such interface, oxygen ions will shift from one side to the other side with lower oxygen concentration. Specifically, since oxygen density of the silicon oxide film 21 is higher between the silicon oxide film 21 and the hafnium oxide film 22, oxygen ions in the silicon oxide film 21 will shift to the side of the hafnium oxide film 22 in the interface between the hafnium oxide film 22 and the silicon oxide film 21. When the oxygen ions shifted this way, an electric dipole (dipole) will be generated at the interface of the different oxide films. This electric dipole will modulate the energy band structure of the oxide films. More specifically, when an electric dipole is produced so that the negative charges are arranged into an oxide film that became the injection side of the electric charge, and the positive charges are arranged into the oxide film located at the opposite side of the injection side of the electric charge, the energy band is modulated so as to reduce barriers to the charge. In other words, the energy band is modulated to further reduce, with respect to the electric charge, the barrier height (electron barriers) of the silicon oxide film 21 during the erasing operation of the semiconductor memory device 31, which increases the tunneling probability of the charge and the leakage current. Consequently, since the charges trapped in the FG electrode 23 can be easily erased during the erasing operation of the semiconductor memory device 31, it is possible to alleviate the stress applied to the TNL film 2 during the erasing operation. As the result, deterioration of the TNL film 2 can be avoided, enabling an improvement in the device property and reliability of the semiconductor memory device 31.

For example, as compared to the hafnium silicon oxynitride film, when the hafnium oxide film is used to form the upper layer film 22, since the film does not contain any silicon atom or nitrogen atom, bonding between hafnium atoms that is not blocked in the upper layer film 22 is present in a large amount, so the upper layer film 22 can easily draw oxygen ions out from the lower layer film 21. Consequently, the electric dipole can be easily produced at the interface.

Moreover, instead of the oxide film, a nitride film, an oxynitride film, or the like, can be used as the upper layer film 22 in this embodiment. Because bonding of hafnium atoms in the upper layer film 22 are not completely blocked, the upper layer film 22 can draw out oxygen ions from the lower layer film 21 so as to easily produce the electric dipole at that interface.

As has been explained before, in this embodiment, the upper layer film 22 is not limited to those containing hafnium atoms; it may include transition metal atoms such as titanium, zirconium, tantalum, lanthanum, or the like. If the upper layer film 22 contains these atoms, it will be easy to remove the charges trapped in the FG electrode 23 during the erasing operation of the semiconductor substrate 31. Moreover, by using inexpensive titanium atoms, manufacturing costs of the semiconductor memory device 31 can be reduced, which is advantageous.

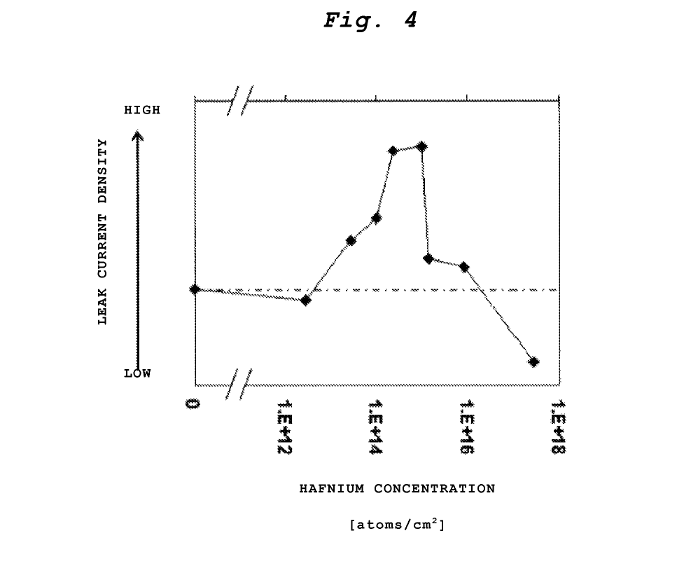

The inventors of this device have investigated the relationship between the leakage current and the concentration of hafnium atoms of the hafnium oxide film. Their research result is shown in FIG. 4, which is a graph showing the relationship of the leakage current density with respect to the concentration of the hafnium atoms. More specifically, by forming the hafnium oxide film with desired concentration of hafnium atoms onto the silicon dioxide film on the silicon substrate, multiple samples of MIS capacitors is obtained. This graph shows the relationship between the leakage current density and the concentration of hafnium atoms when the electrons are injected from the upper electrode side (the side of the hafnium oxide film) with respect to these samples. In FIG. 4, the horizontal axis represents the concentration of hafnium atoms while the vertical axis represents the leakage current density. Comparison with the samples that failed to form a hafnium oxide film (that is, zero concentration of hafnium atoms as shown in FIG. 4) is also made.

As shown in FIG. 4, when the hafnium oxide film is formed, it is found that leakage current increases, as compared to that when only silicon oxide film is formed without forming hafnium oxide film (as in a conventional device) . Additionally. the charge tunneling probability also increases by forming the hafnium oxide film. As can be seen in FIG. 4, in order to increase this leakage current, the concentrations of hafnium atoms is greater than 1e13 atoms/cm² and less than 1e16 atoms/cm² as the surface density. There is an optimum value of the concentration of hafnium atoms for obtaining the effect of increasing the leakage current. Then, hafnium atom concentration adjusts to depend on the desired characteristics required for the semiconductor memory device 31.

In one embodiment, by using a laminated structure made from a silicon oxide film (lower layer film) 21 and a hafnium oxide film (upper layer film) 22 as the TNL film 2, it is possible to improve erasing characteristics of the semiconductor memory device 31, further avoid the deterioration of the TNL film 2, and eventually improve the durability, charge retention ability and reliability of the semiconductor memory device 31. (Modified examples of this embodiment)

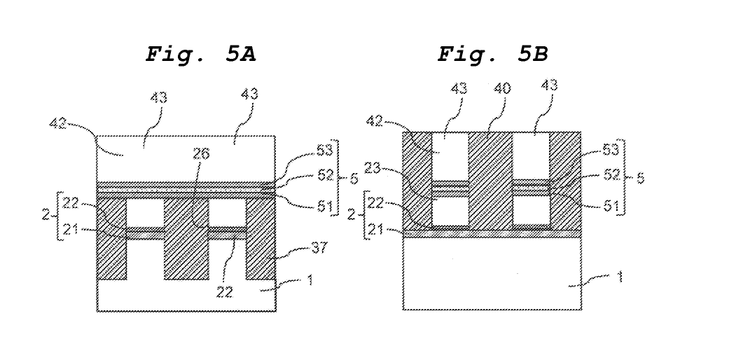

Although the above explanation is based on the semiconductor memory device 31 with a three-dimensional structure as shown in FIGS. 2A and 2B, it is not limited to such a three-dimensional structure. A flat-structured (planar) semiconductor memory device 31 with a reduced parasitic capacitance as shown in FIGS. 5A and 5B may also be applied. As has been explained before, a plan view of the memory cell area of this flat-structured semiconductor memory device 31 is shown in FIG. 1, and its cross-sectional view is shown in FIGS. 5A and 5B. More specifically, FIG. 5A is a cross-sectional view of the semiconductor memory device 31 taken along the A-A line of FIG. 1. FIG. 5B is a cross-sectional view of the semiconductor memory device 31 taken along the B-B′ line of FIG. 1. In this modified example, the IPD film 5 is formed so that it is in parallel with the back surface of the semiconductor substrate 1; however, other structures are the same as the structure of the semiconductor memory device 31 shown in FIGS. 2A and 2B as explained before, so detailed descriptions thereof will be omitted. In addition, the semiconductor memory device 31 in FIGS. 5A and 5B that have the same structure and the portion having the same function will be given the same notation as that in FIGS. 2A and 2B.

In this modified example, the upper layer film 22 is not limited to the shape of a film. An atomic layer consisting of atoms, such as hafnium atoms, may be provided between the lower layer film 21 and the FG electrode 23.

Also in this modified example, by using the lower layer film 21 formed by the silicon oxide film or the like, and the upper layer film 22 formed by the hafnium oxide film or the like, as the TNL film 2, the erasing characteristic of the semiconductor memory device 31 can be improved, further avoiding the deterioration of the TNL film 2, and eventually increase the durability, charge retention ability and reliability of the semiconductor memory device 31.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein maybe made without departing from the spirit of the inventions. The accompanying claims and their equivalents are intended to cover such forms or modifications as would fall within the scope and spirit of the inventions.

What is claimed is:

1. A nonvolatile semiconductor memory device, comprising:
a semiconductor substrate;
a first insulation film formed on the semiconductor substrate;
a charge storage film formed on the first insulation film;
a second insulation film formed on the charge storage film; and
a control electrode formed on the second insulation film,
wherein the first insulating film includes a lower layer film containing silicon that is formed on the semiconductor substrate, and a layer of transition metal atoms are disposed between the lower layer film and the charge storage film.

2. The nonvolatile semiconductor memory device of claim 1, wherein the transition metal atoms contain at least one of hafnium, titanium, zirconium, tantalum or lanthanum.

3. The nonvolatile semiconductor memory device of claim 2, wherein a concentration of the transition metal atoms between the lower film and the charge storage film is from 1e13 atoms/cm² to 1e16 atoms/cm².

4. The nonvolatile semiconductor memory device of claim 2, wherein the transition metal atoms between the lower film and the charge storage film form a layer of either an oxide film, a nitride film, a boride film or a sulfide film.

5. The nonvolatile semiconductor memory device of claim 1, wherein the transition metal atoms between the lower film and the charge storage film form a layer of either an oxide film, a nitride film, a boride film or a sulfide film.

6. The nonvolatile semiconductor memory device of claim 5, wherein the transition metal atoms contain at least one of hafnium, titanium, zirconium, tantalum or lanthanum.

7. The nonvolatile semiconductor memory device of claim 6, wherein a concentration of the transition metal atoms between the lower film and the charge storage film is from 1e13 atoms/cm² to 1e16 atoms/cm².

8. The nonvolatile semiconductor memory device of claim 1, wherein a concentration of the transition metal atoms between the lower film and the charge storage film is from 1e13 atoms/cm² to 1e16 atoms/cm².

9. A nonvolatile semiconductor memory device, comprising:
a semiconductor substrate;
a first insulation film formed on the semiconductor substrate;
a charge storage film formed on the first insulation film;
a second insulation film formed on the charge storage film; and
a control electrode formed on the second insulation film,
wherein the first insulation film is formed on the semiconductor substrate, and includes a lower layer film containing silicon and an upper layer film formed on the lower layer film, the upper layer film containing a concentration of transition metal atoms from 1e13 atoms/cm² to 1e16 atoms/cm².

10. The nonvolatile semiconductor memory device of claim 9, wherein the transition metal atoms contains at least one of hafnium, titanium, zirconium, tantalum or lanthanum.

11. The nonvolatile semiconductor memory device of claim 9, wherein the upper layer film contains one of an oxide film, a nitride film or an oxynitride film.

12. The nonvolatile semiconductor memory device of claim 11, wherein the transition metal atoms contain at least one of hafnium, titanium, zirconium, tantalum or lanthanum.

13. The nonvolatile semiconductor memory device of claim 9, wherein the upper layer film contains a hafnium oxide film.

14. The nonvolatile semiconductor memory device of claim 9, wherein the lower layer film is formed of silicon oxide.

15. A manufacturing method for a nonvolatile semiconductor memory device, the method comprising:
forming a lower film formed by depositing an insulating film containing silicon on the semiconductor substrate,
forming an upper layer film on the lower layer film, the upper layer film having a concentration of transition metal atoms from 1e13 atoms/cm² to 1e16 atoms/cm²,
forming a charge storage film on the upper film,
forming a second insulation film on the charge storage film, and
forming a control electrode on the second insulation film.

16. The method of claim 15, wherein the upper layer film contains an oxide film, a nitride film or an oxynitride film.

17. The method of claim 16, wherein the upper layer film contains a hafnium oxide film.

18. The method of claim 16, wherein the upper layer film contains at least one of hafnium, titanium, zirconium, tantalum or lanthanum.
